(19) United States
(12) Patent Application Publication
(10) Pub. No.: US 2006/0284249 A1
(43) Pub. Date: Dec. 21, 2006

(54) Impurity co-implantation to improve transistor performance

(76) Inventors: Chien-Hao Chen, I Lan County (TW); Chun-Feng Nieh, Baoshan Township (TW); Tze-Liang Lee, Hsinchu (TW); Shih-Chang Chen, Hsin-Chu (TW)

Correspondence Address: SLATER & MATSIL, L.L.P., 17950 PRESTON ROAD, SUITE 1000, DALLAS, TX, 75252, US

(21) Appl. No.: 11/157,515

(22) Filed: Jun. 21, 2005

(51) Int. Cl. H01L 21/8238

(52) U.S. Cl. 257/344

(57) ABSTRACT

A pMOS transistor having reduced diffusion from source/drain regions and a method of forming the same are provided. The pMOS transistor includes a source/drain region doped with a p-type impurity and a diffusion-retarding material in a semiconductor substrate. The pMOS transistor further includes a gate dielectric over a channel region in the semiconductor substrate, a gate electrode over the gate dielectric, and a lightly doped source/drain (LDD) region substantially aligned with an edge of the gate electrode. The diffusion-retarding material preferably includes carbon, fluorine, nitrogen, and combinations thereof.

### CROSS-REFERENCE TO RELATED APPLICATIONS

This application relates to the following co-pending and commonly assigned patent application: U.S. patent application Ser. No. 11/114,567, filed Apr. 25, 2005, entitled “Profile Confinement to Improve Transistor Performance”, which application is incorporated herein by reference.

### TECHNICAL FIELD

This invention relates generally to transistor manufacturing processes, and more particularly to reducing impurity diffusion from source/drain regions of pMOS semiconductor devices.

### BACKGROUND

As the dimensions of transistors are scaled down, shallower source/drain junctions are required to maintain short channel characteristics. The scaling of the source/drain junction worsens the sheet resistance of the source/drain and deteriorates the polysilicon gate depletion, leading to a degraded current drivability.

To reduce polysilicon gate depletion effects and lower source/drain resistance, source/drain dopant concentration is preferably increased. However, with greater concentration, diffusion of the source/drain dopant is also increased, leading to significantly degraded short channel characteristics.

One of the commonly used methods to effectively control diffusion is to lower the temperatures of the annealing processes, such as rapid thermal annealing (RTA). The activation of the source/drain impurities, however, is affected, resulting in degraded drive current.

Other methods have also been explored to reduce the diffusion and confine the profile of the dopants. U.S. Pat. No. 5,885,861 discusses a method of confining the diffusion of p-type or n-type impurities. As shown in FIG. 1, a gate electrode 6 is formed over a substrate 2. N-type dopants and p-type dopants are introduced into the gate electrode 6 and the lightly diffused source/drain (LDD) regions 8 of the nMOS devices and the pMOS devices, respectively. Arrows 10 symbolize the implanting process. For n-type devices, nitrogen and fluorine are co-implanted into the gate electrode 6 and LDD regions 8, and for p-type devices, nitrogen and carbon are co-implanted into the gate electrode 6 and LDD regions 8. Nitrogen, carbon, and fluorine have the function of retarding the diffusion of respective dopants. Therefore, the diffusion of the dopants is controlled during subsequent anneal steps, and thus the LDD regions 8 have higher impurity concentrations and more confined profiles.

To achieve better results, n-type impurities also need to be confined. U.S. Patent Publication No. 2004/0102013 discusses a method for confining the profile of phosphorus in deep source/drain regions 16 of nMOS devices, as illustrated in FIG. 2. After the formation of a gate electrode 12 over a substrate 20, LDD regions 14 are formed by introducing an n-type dopant such as arsenic. Spacers 11 are then formed. Arrows 22 symbolize the impurity implants. Phosphorus is introduced to form deep source/drain regions 16. Carbon or fluorine is also implanted into the same regions. The addition of carbon or fluorine makes relatively high concentrations of phosphorus possible since less is diffused away, and transistor drive current is improved without unduly compromising the short channel characteristics.

However, these approaches do not target the diffusion of impurities from source/drain regions in pMOS devices. Although U.S. Pat. No. 5,885,861 presents that carbon can be used to retard the p-type dopant diffusion in LDD regions of the PMOS devices, the effects of the dopant species and implantation conditions (such as the doses, implantation energy, and ratio of doses), particularly for doping source/drain regions of PMOS devices, are not discussed. It is to be noted that the species and implantation conditions of the diffusion-retarding materials need to be optimized for different junctions in order to get the diffusion-retarding phenomenon, and no satisfactory result will be obtained if the species and implantation conditions for NMOS devices are simply applied on PMOS devices without changing.

Diffusion from source/drain regions can affect the channel region. This is particularly true for very small devices such as devices manufactured using 65 nm technologies and beyond. In such small scales, source/drain impurities are more likely to diffuse to lightly doped regions, and even to the channel region. Particularly, the sheet resistance in the source/drain regions increases due to lowered impurity concentration caused by diffusion. A method to suppress diffusion and to improve the short channel characteristics of pMOS devices, therefore, is needed.

### SUMMARY OF THE INVENTION

The preferred embodiment of the present invention provides a pMOS transistor having reduced diffusion from source/drain regions and a method of forming the same.

In accordance with one aspect of the present invention, the pMOS transistor includes a source/drain region doped with a p-type impurity and at least one diffusion-retarding material. The pMOS transistor further includes a gate dielectric over a channel region in the semiconductor substrate, a gate electrode over the gate dielectric, and a lightly doped source/drain (LDD) region substantially aligned with an edge of the gate electrode. The diffusion-retarding material preferably includes carbon, fluorine, nitrogen, and combinations thereof. The gate electrode is preferably doped with the same impurities in the source/drain region.

In accordance with another aspect of the present invention, the method includes forming a source/drain region doped with a p-type impurity and a diffusion-retarding material. The method further includes forming a gate dielectric over a channel region in a semiconductor substrate, forming a gate electrode over the gate dielectric, forming a lightly doped region by implanting an additional p-type impurity using the gate electrode as a mask, and forming a gate spacer along a sidewall of the gate electrode. The p-type impurity and the diffusion-retarding material can be implanted simultaneously or sequentially.

Due to the co-implanted diffusion-retarding material, diffusion from the source/drain region is reduced. As a result, the sheet resistance in the source/drain region is lowered, junctions can be formed with greater abruptness, and short channel characteristics are improved.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional method of making transistors, wherein nitrogen and fluorine are used to retard diffusion of n-type impurities, and nitrogen and carbon are used to retard diffusion of p-type impurities;

FIG. 2 illustrates a conventional method of making nMOS transistors by co-implanting carbon or fluorine with phosphorus;

FIGS. 3 through 7 are cross-sectional views of intermediate stages in the manufacture of a pMOS transistor embodiment; and

FIG. 8 illustrates concentrations of boron as a function of depth.

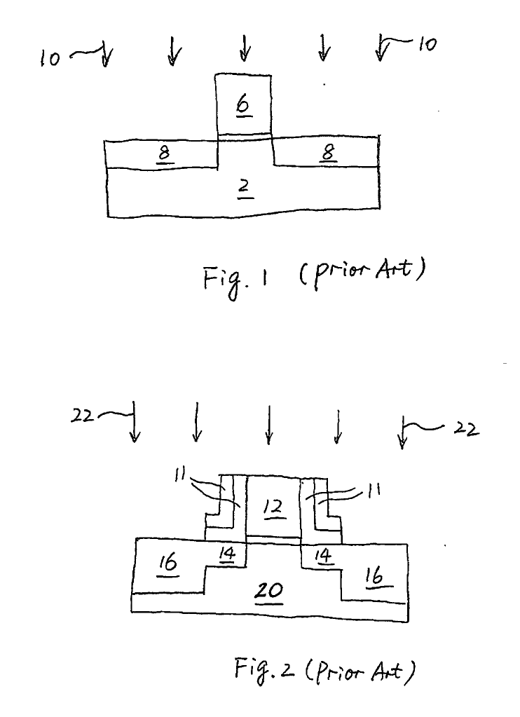

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The cross-sectional views of the intermediate stages in the manufacture of the preferred embodiments are illustrated in FIGS. 3 through 7, wherein like reference numbers are used to designate like elements throughout the various views and illustrative embodiments of the present invention.

FIG. 3 illustrates a gate dielectric 44 and a gate electrode 46 formed on a substrate 40. As known in the art, the forming of the gate dielectric includes forming a gate dielectric layer on the substrate 40. The substrate 40 preferably comprises common substrate materials such as silicon, SiGe, strained silicon on SiGe, silicon on insulator (SOI), silicon germanium on insulator (SGOI), germanium on insulator (GOI), and the like. The gate dielectric layer preferably has a high k value. A gate electrode layer, preferably comprising polysilicon, metals, or metal silicides, is formed on the gate dielectric layer. The gate electrode layer and the gate dielectric layer are then patterned to form the gate electrode 46 and the gate dielectric 44, respectively.

An optional pre-amorphization implantation (PAI) is performed on the gate electrode 46 and exposed substrate 40 to reduce dopant channeling effects and enhance dopant activation. In the preferred embodiment, germanium and/or xenon are implanted. The pre-amorphization implantation prevents subsequently doped impurities from channeling through spaces between the crystal lattice structure and reaching depths greater than desired. At least a top portion of the (polysilicon) gate electrode 46 and exposed portions of the (single crystalline) substrate 40 are turned into an amorphous state as a result of the PAI.

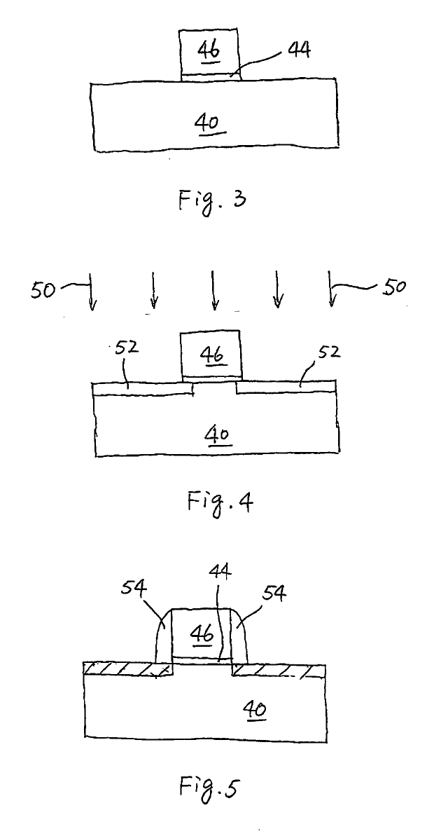

FIG. 4 illustrates the formation of lightly doped drain/source (LDD) regions 52. The LDD regions 52 are formed by implanting p-type impurities, such as boron and/or BF₂, and the like. Arrows 50 symbolize the implanting, which is preferably substantially vertical. An optional LDD dopant activation may also be performed.

FIG. 5 illustrates the formation of spacers 54 along the sidewalls of the gate dielectric 44 and gate electrode 46. As is well known in the art, spacers 54 are preferably formed by blanket depositing a dielectric layer over an entire region, then anisotropically etching to remove the dielectric layer from horizontal surfaces, and thus leaving spacers 54.

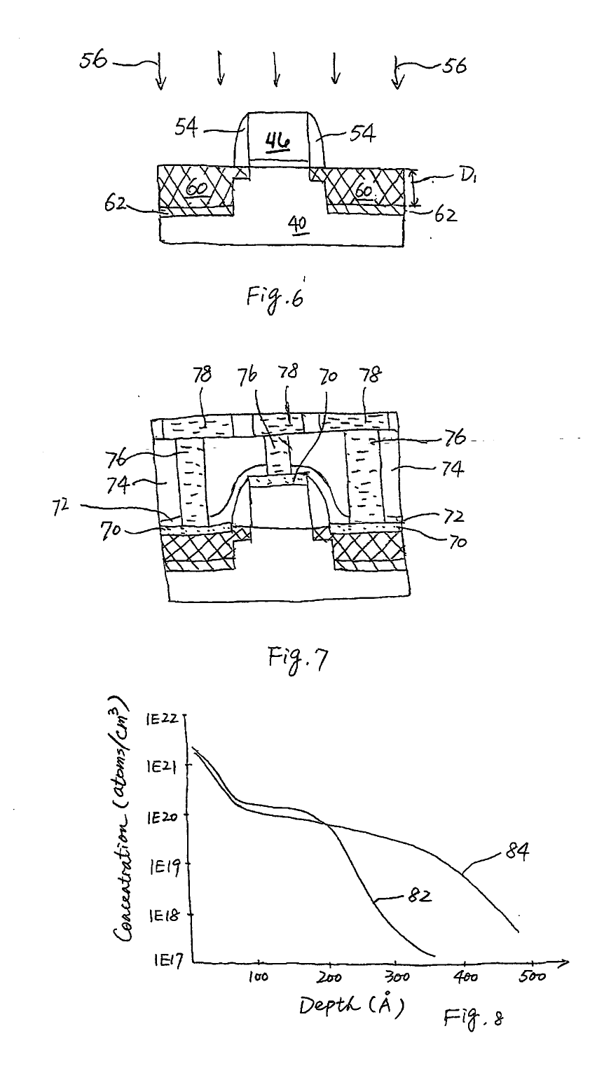

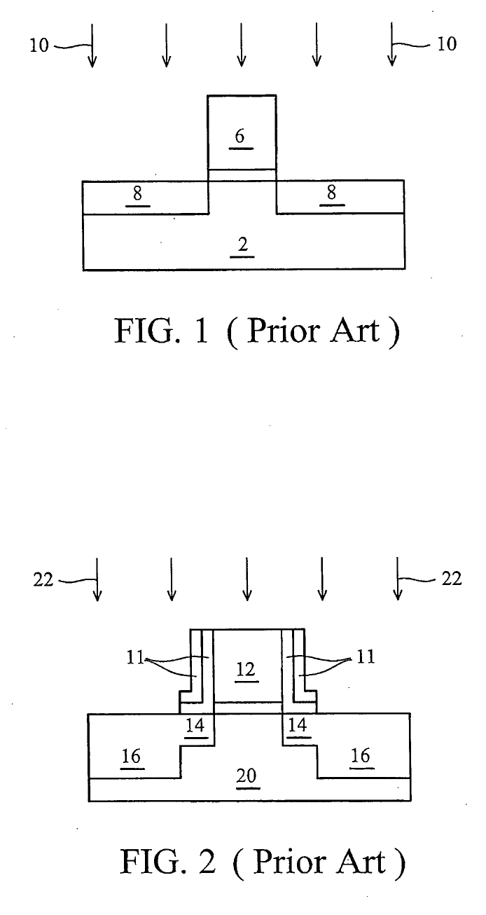

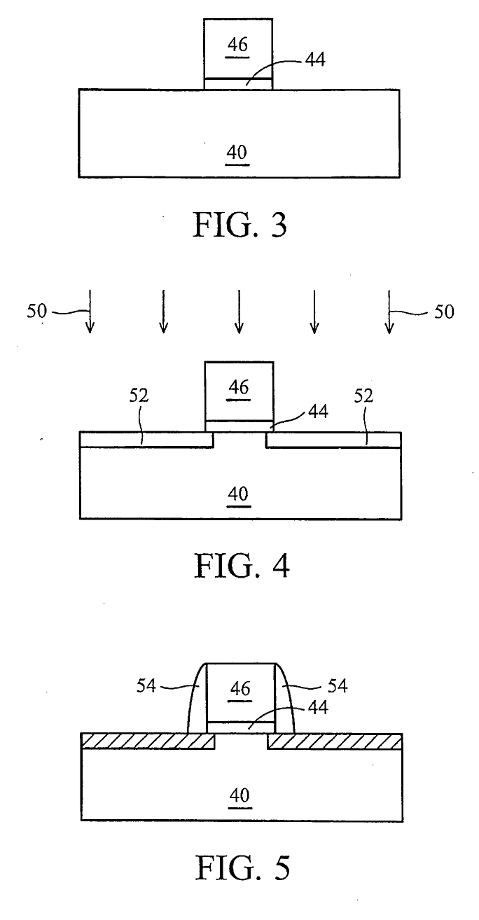

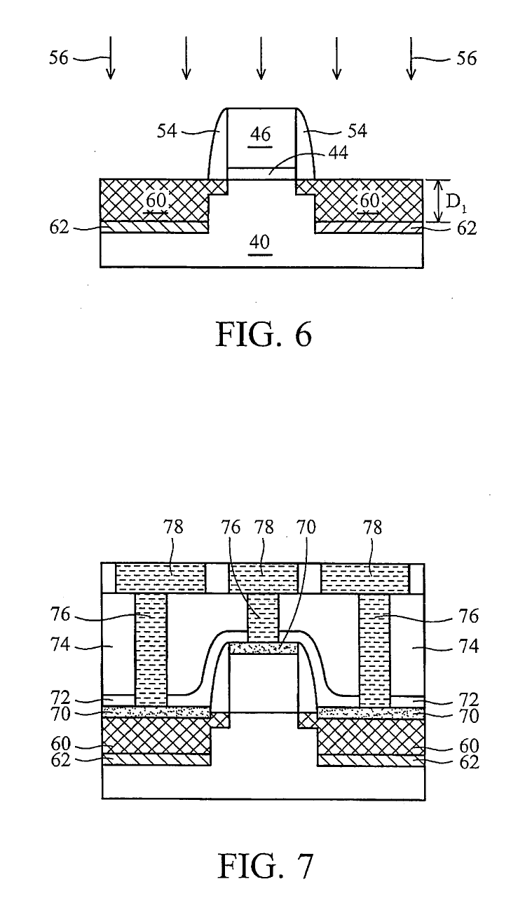

FIG. 6 illustrates processes for forming source/drain regions 60 and diffusion-retarding regions 62. For illustration purposes, the source/drain regions 60 and diffusion-retarding regions 62 are shown as distinctive regions. In practical cases, they can be one combined region or separate regions. Diffusion-retarding impurities and p-type impurities for forming source/drain regions are implanted, as symbolized by arrows 56, and the spacers 54 are used as masks. P-type impurities, such as boron and/or BF₂, are preferably implanted with a concentration of greater than about 1E15/cm³, more preferably between about 1E15/cm³ and about 1E17/cm³.

FIG. 6 also illustrates the forming of diffusion-retarding regions 62 by implanting diffusion-retarding impurities. Diffusion-retarding impurities preferably comprise carbon, fluorine, nitrogen, and combinations thereof. It is to be noted that the diffusion-retarding region 62 preferably extends from the surface of the substrate 40 into the substrate. Therefore, the diffusion-retarding regions 62 include entire respective source/drain regions 60, and the portions extending below respective source/drain regions 60. The preferred dose for implanting the diffusion-retarding elements is between about 1E14/cm2 and about 1E16/cm2. The depth D1 of the implantation is determined partially by the implantation energy used, which is preferably between about 1 KeV and about 50 KeV, resulting in a preferred nominal depth of from about 5 nm to about 100 nm. Preferably, p-type impurities and diffusion-retarding impurities have a concentration ratio of between about 0.1 and about 10.

The source/drain regions 60 preferably substantially overlap the respective diffusion retarding regions 62. To have an optimized effect, the diffusion-retarding regions 62 preferably substantially enclose the source/drain regions 60, although the source/drain regions 60 may also enclose diffusion-retarding regions 62. It is preferred that the diffusion-retarding material has a high concentration along the borders of the source/drain region, particularly the bottom border. The depth D₁ of the diffusion-retarding material can be adjusted by adjusting implanting power. In the preferred embodiment, source/drain regions 60 and diffusion-retarding regions 62 can be formed sequentially, and the order can be reversed without affecting the characteristics of the resulting device. In other embodiments, source/drain regions 60 and diffusion-retarding regions 62 are formed simultaneously.

When the diffusion-retarding regions 62 and source/drain regions 60 are formed, the same impurities are preferably doped into the gate electrode 46 as well. If desired, however, the gate electrode 46 could be masked during the implanting step. Through the doping of p-type impurities and diffusion-retarding materials, not only is the dopant concentration increased and the depletion effect reduced, but the diffusion of the impurities into the gate electrode 46 and into the gate dielectric 44 is also reduced, and thus the reliability of the device is improved.

The dopants introduced in previously discussed processes are then activated. The activation can be conducted using commonly used methods such as furnace annealing, rapid thermal annealing (RTA), laser annealing, flash annealing, etc. During the activation, the dopants in the source/drain regions 60 and gate electrode 46 will diffuse somewhat. However, with the co-implantation of diffusion-retarding impurities on the diffusion paths, the diffusion is reduced. Less diffusion results in higher impurity concentration in the source/drain regions 60, hence higher current drivability. Particularly, less diffusion of impurities into the channel region improves the short channel characteristics.

FIG. 7 illustrates a structure after the formation of silicides 70, a contact etch stop layer (CESL) 72, an inter-layer dielectric (ILD) 74, contact plugs 76, and metal lines 78. To form the suicides 70, a thin layer of metal (not shown), such as cobalt, nickel, erbium, molybdenum, platinum, or the like, is first formed over the device. The device is then annealed to form silicides 70 between the deposited metal and the underlying exposed silicon regions. The remaining metal layer is then removed. The CESL 72 is preferably blanket deposited. This layer serves two purposes. First, it provides a stress to the underlying device and enhances carrier mobility. Second, it protects underlying regions from being damaged during etching of the subsequently formed ILD layer. Next, the ILD 74 is deposited over the surface of the CESL 72 and patterned (to form contact openings). The contact plugs 76 and metal lines 78 are then formed. The processes of forming such features are well known in the art and therefore are not repeated herein.

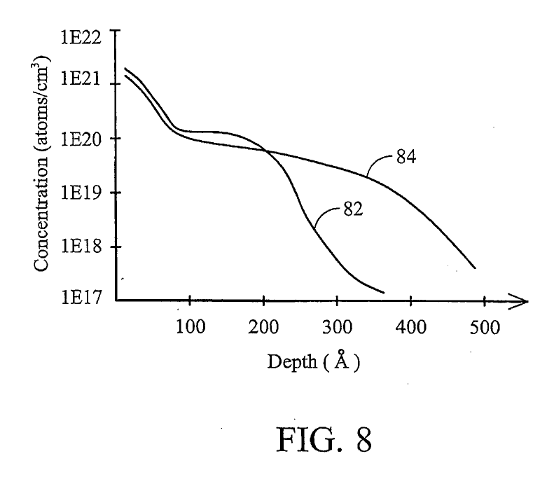

The effect of the preferred embodiments of the present invention is shown in FIG. 8, which illustrates boron concentrations as a function of depth. Line 82 is obtained from a first sample device that had a pre-amorphization implantation and was co-implanted with boron and carbon. Line 84 is obtained from a second sample device that had only boron implanted. Line 82 has a greater abruptness than line 84. From line 84, it is observed that the junction depth of the second sample device is about 404 Å. Due to retarded diffusion, the junction depth of the first sample device is about 256 Å, less than that of the second sample device. The sheet resistance of the first sample device relative to its junction depth is also lower than that of the second sample device. Therefore, FIG. 8 demonstrates the beneficial effects of diffusion-retarding impurities on the distribution of boron.

Further experiment results have revealed that devices implanted with boron and/or BF₂, and co-implanted with fluorine or carbon have significantly lower sheet resistances than devices having no fluorine and carbon co-implanted.

The preferred embodiments of the present invention significantly improve the pMOS device profile through the co-implantation of carbon/fluorine/nitrogen. The preferred embodiments of the present invention have several advantageous features. Firstly, less diffusion results in a higher activation level (or concentration) in desired regions, and thus sheet resistance is lowered. The polysilicon gate depletion effect is also reduced. Secondly, greater abruptness means less impurity is diffused to the gate dielectric, resulting in better gate oxide integrity and threshold voltage control. Thirdly, retarded diffusion enables higher concentration in the gate electrode and source/drain regions, and thus the saturation current is increased.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A pMOS transistor comprising:
a source/drain region doped with a p-type impurity and a diffusion-retarding material.

2. The pMOS transistor of claim 1 wherein the diffusion-retarding material is selected from the group consisting essentially of carbon, fluorine, nitrogen, and combinations thereof.

3. The pMOS transistor of claim 1 wherein the p-type impurity is selected from the group consisting essentially of boron, BF₂, and combinations thereof.

4. A semiconductor device comprising:
a semiconductor substrate;
a gate dielectric over a channel region in the semiconductor substrate;
a gate electrode over the gate dielectric;
a lightly doped source/drain (LDD) region substantially aligned with an edge of the gate electrode, the LDD region comprising a p-type impurity;
a gate spacer along an edge of the gate electrode;
a source/drain region having a high doping concentration in the semiconductor substrate substantially aligned with an edge of the gate spacer, the source/drain region comprising a p-type impurity; and
a diffusion-retarding region comprising a diffusion-retarding material in the semiconductor substrate substantially aligned with the edge of the gate spacer.

5. The semiconductor device of claim 3 wherein the diffusion-retarding material is selected from the group consisting essentially of carbon, fluorine, nitrogen, and combinations thereof.

6. The semiconductor device of claim 3 wherein the diffusion-retarding region substantially overlaps the source/drain region.

7. The semiconductor device of claim 3 wherein the diffusion-retarding region is substantially deeper than the source/drain region.

8. The semiconductor device of claim 3 wherein the p-type impurity is selected from the group consisting essentially of boron, BF₂, and combinations thereof.

9. The semiconductor device of claim 8 wherein the p-type impurity in the source/drain region has a concentration of greater than about 1E15/cm³.

10. The semiconductor device of claim 3 wherein the gate electrode comprises a diffusion-retarding material and a p-type impurity.

11. The semiconductor device of claim 10 wherein the gate electrode comprises the same diffusion-retarding material and the same p-type impurity as the source/drain region.

12. The semiconductor device of claim 3 wherein the diffusion-retarding material has a first concentration, and the p-type impurity has a second concentration, and wherein the first and second concentrations have a ratio of between about 0.1 and about 10.

13. The semiconductor device of claim 3 wherein the semiconductor substrate is a silicon substrate, and wherein the source/drain region comprises at least one of germanium and xenon.

14. A semiconductor device comprising:
a gate dielectric over a channel region in a semiconductor substrate;
a gate electrode over the gate dielectric;
a lightly doped source/drain (LDD) region substantially aligned with an edge of the gate electrode, the LDD region comprising a p-type impurity;
a gate spacer along an edge of the gate electrode;
a heavily doped source/drain region in the semiconductor substrate substantially aligned with an edge of the gate spacer, the source/drain region comprising a p-type impurity and at least one diffusion-retarding material; and
wherein the p-type impurity and the diffusion-retarding material have a concentration ratio of between about 0.1 and 10.

15. The device of claim 13 wherein the diffusion-retarding material is selected from the group consisting essentially of carbon, fluorine, nitrogen, and combinations thereof.

16. The device of claim 13 wherein the p-type impurity is selected from the group consisting essentially of boron, BF₂, and combinations thereof.

17. The pMOS transistor of claim 1 wherein the diffusion-retarding material comprises nitrogen.

18. The semiconductor device of claim 1 wherein the diffusion-retarding material has a first concentration, and the p-type impurity has a second concentration, and wherein the first and second concentrations have a ratio of between about 0.1 and about 10.
